(19) United States
(12) Patent Application Publication
(10) Pub. No.: US 2026/0031767 A1
(43) Pub. Date: Jan. 29, 2026

(54) SAMPLE AND HOLD AMPLIFIERS, HIGH-SPEED ANALOG-TO-DIGITAL CONVERTERS, AND ELECTRONIC DEVICES

(71) Applicant: ZHEJIANG UNIVERSITY, Zhoushan (CN)

(72) Inventors: Zhiwei XU, Zhoushan (CN); Zhiyang LI, Zhoushan (CN); Xuehao GUO, Zhoushan (CN); Hao FANG, Zhoushan (CN); Fuli TIAN, Zhoushan (CN); Zelin JIA, Zhoushan (CN); Chunyi SONG, Zhoushan (CN)

(73) Assignee: ZHEJIANG UNIVERSITY, Zhoushan (CN)

(21) Appl. No.: 19/346,522

(22) Filed: Sep. 30, 2025

(30) Foreign Application Priority Data
Oct. 24, 2024 (CN) 202411487026.3

(51) Int. Cl. H03F 1/32; H03F 3/16; H03M 1/06

(52) U.S. Cl. CPC H03F 1/3205; H03F 3/16; H03M 1/0604

(57) ABSTRACT

The present disclosure relates to a sample and hold amplifier, a high-speed analog-to-digital converter, and an electronic device. The sample and hold amplifier, the high-speed analog-to-digital converter, and the electronic device are provided in the present disclosure. By arranging a first-stage non-Forster circuit and a second-stage non-Forster circuit in the sample and hold amplifier, and by using a negative capacitor to cancel out an internal parasitic capacitor, the first-stage non-Forster circuit and the second-stage non-Forster circuit may reduce nonlinear distortion caused by the parasitic capacitor and improve the linearity of the sample and hold amplifier. In addition, the first-stage non-Forster circuit focuses on providing preliminary gain and parasitic capacitor compensation, ensuring that the circuit may effectively process an input signal and reduce an impact of non-dominant poles on overall performance. The second-stage non-Forster circuit further optimizes gain and stability, thereby enabling the sampling and holding circuit to achieve faster stability overall.

### CROSS-REFERENCE TO RELATED APPLICATIONS

This application claims priority to the Chinese Patent Application No. 202411487026.3, filed on Oct. 24, 2024, the contents of which are hereby incorporated by reference.

### TECHNICAL FIELD

The present disclosure relates to the field of electronic and electrical technology, and in particular, to a sample and hold amplifier, a high-speed analog-to-digital converter, and an electronic device.

### BACKGROUND

With the increasing demand for higher data rates and larger data bandwidth in fields such as mobile communications, optical fiber communications, and wireless networks, high-speed analog-to-digital converters (ADCs) play a crucial role in addressing the growing data bandwidth requirements. The high-speed analog-to-digital converters rapidly convert analog signals into high-precision digital signals, thereby supporting high-speed data transmission, real-time signal processing, and complex modulation and demodulation processes.

To achieve a sampling rate of Giga-Samples per second (GS/s), various time-interleaved architectures are adopted to improve a speed and efficiency of a sub analog-to-digital converter. However, when further improving performance, mismatches among channels become a critical issue. To address this issue, various types of sample and hold amplifiers are applied in the high-speed analog-to-digital converters. However, existing sample and hold amplifiers have linearity limitations, which significantly affect the overall performance of the analog-to-digital converters.

### SUMMARY

One or more embodiments of the present disclosure provide a sample and hold amplifier wherein the sample and hold amplifier comprises a cascaded configuration of a filter capacitor, a first-stage non-Forster circuit, a second-stage non-Forster circuit, and an output circuit, wherein
An input terminal of the filter capacitor is connected to an output terminal of the output circuit via a first control switch;
The first-stage non-Forster circuit includes an equivalent tristate gate and a first equivalent negative capacitor; wherein an enable control terminal of the equivalent tristate gate is connected to a voltage source, and an input terminal of the equivalent tristate gate and an first terminal of the first equivalent negative capacitor are connected to form an input terminal of the first-stage non-Forster circuit; an output terminal of the equivalent tristate gate forms an output terminal of the first-stage non-Forster circuit; and a second terminal of the first equivalent negative capacitor is grounded;
The second-stage non-Forster circuit includes a first equivalent non-gate and a second equivalent negative capacitor; wherein an input terminal of the first equivalent non-gate and a first terminal of the second equivalent negative capacitor are connected to form an input terminal of the second-stage non-Forster circuit; an output terminal of the first equivalent non-gate forms an output terminal of the second-stage non-Forster circuit; and a second terminal of the second equivalent negative capacitor is grounded;
The output circuit includes a second equivalent non-gate and a load capacitor; wherein an input terminal of the second equivalent non-gate forms an input terminal of the output circuit; an output terminal of the second equivalent non-gate and a first terminal of the load capacitor are connected to form an output terminal of the output circuit; and an second terminal of the load capacitor is grounded; and
The first-stage non-Forster circuit and the second-stage non-Forster circuit cancel an internal parasitic capacitor by utilizing an equivalent negative capacitor for improved linearity and faster stability.

One or more embodiments of the present disclosure provide a high-speed analog-to-digital converter, wherein the high-speed analog-to-digital converter comprises at least one sample and hold amplifier.

One or more embodiments of the present disclosure provide an electronic device, the electronic device includes the high-speed analog-to-digital converter.

### BRIEF DESCRIPTION OF THE DRAWINGS

FIG. 1 is a diagram illustrating an exemplary circuit of a sample and hold amplifier according to some embodiments of the present disclosure;

FIG. 2 is a schematic diagram illustrating the performance of a sample and hold amplifier according to some embodiments of the present disclosure;

FIG. 3 is another schematic diagram illustrating an exemplary circuit of a sample and hold amplifier according to some embodiments of the present disclosure;

FIG. 4 is a schematic diagram illustrating an exemplary circuit of a tristate circuit according to some embodiments of the present disclosure;

FIG. 5 is a schematic diagram illustrating an exemplary circuit of a two-stage amplifier with a non-Forster circuit according to some embodiments of the present disclosure;

FIG. 6 is a schematic diagram illustrating a change curve of equivalent capacitances of two feedback capacitors in a two-stage amplifier with a non-Forster circuit according to some embodiments of the present disclosure;

FIG. 7 is a schematic diagram illustrating a test result of a sample and hold amplifier according to some embodiments of the present disclosure;

FIG. 8 is a schematic diagram illustrating a transient response of a sample and hold amplifier according to some embodiments of the present disclosure;

FIG. 9 is a schematic diagram illustrating an exemplary circuit of a high-speed analog-to-digital converter according to some embodiments of the present disclosure;

FIG. 10 is a schematic diagram illustrating an exemplary circuit of an input buffer according to some embodiments of the present disclosure;

REFERENCE NUMERALS: 1: first-stage non-Foster circuit; 2: second-stage non-Foster circuit; 3: output circuit; CS: filter capacitor; K1: first control switch; T1: equivalent tristate gate; CN1: first equivalent negative capacitor; N1: first equivalent non-gate; CN2: second equivalent negative capacitor; N2: second equivalent non-gate; CL: load capacitor; T11: first tristate buffer; T12: second tristate buffer; C1: first capacitor; C2: second capacitor; K2: second control switch; M1: first Metal Oxide Semiconductor Field Effect Transistor (MOSFET); M2: second MOSFET; K3: third control switch; N11: first non-gate; N12: second non-gate; C3: third capacitor; C4: fourth capacitor; N21: third non-gate; N22: fourth non-gate; CF: feedback capacitor; 91: sample and hold amplifier; 92: input buffer; 93: sub analog-to-digital converter; R1: first resistor; R2: second resistor; C5: fifth capacitor; C6: sixth capacitor; M3: third MOSFET; M4: fourth MOSFET; M5: fifth MOSFET; M6: sixth MOSFET; R3: third resistor; R4: fourth resistor.

### DETAILED DESCRIPTION

Exemplary embodiments will be described in detail here, with examples thereof illustrated in the accompanying drawings. When the following description refers to the accompanying drawings, unless otherwise indicated, the same numbers in different drawings denote the same or similar elements. The implementations described in the following exemplary embodiments do not represent all implementations consistent with the present disclosure.

The terminology used in the present disclosure is for the purpose of describing particular embodiments only and is not intended to limit the present disclosure. The singular forms “a,” “the,” and “the” used in the present disclosure are also intended to include plural forms, unless the context clearly indicates otherwise. It should also be understood that the term “and/or” used herein refers to and includes any or all possible combinations of one or more associated listed items.

It should be understood that although terms such as first, second, third, etc. may be used in the present disclosure to describe various information, this information should not be limited by these terms. These terms are only used to distinguish information of the same type from each other. For example, without departing from the scope of the present disclosure, first information may also be referred to as second information, and similarly, second information may also be referred to as first information. Depending on the context, the word “if” as used herein may be interpreted as “when,” “upon,” or “in response to determining.”

High-speed analog-to-digital converters (ADCs) play a crucial role in meeting the increasing data bandwidth demands of modern communication systems. To achieve a high sampling rate, various time-interleaved structures have emerged to enhance the speed and efficiency of sub analog-to-digital converters. However, in the absence of a sample and hold amplifier (THA), if a count of the sub analog-to-digital converters is further increased, the spurious-free dynamic range (SFDR) of the high-speed analog-to-digital converters is significantly reduced due to bandwidth mismatch and time skew among channels.

To solve this problem, the sample and hold amplifier is provided in the high-speed analog-to-digital converter. However, traditional sample and hold amplifiers have limitations in linearity.

The sample and hold amplifier provided by embodiments of the present disclosure breaks the trade-off between loop gain and phase margin in traditional sample and hold amplifiers by introducing a negative capacitor, achieving sufficient loop gain and fast stabilization.

A parasitic capacitor of the traditional sample and hold amplifier limits non-dominant poles, reducing balanced loop gain and stabilization speed. An internal parasitic capacitor of the sample and hold amplifier may be canceled by introducing a negative capacitor, thereby pushing a non-dominant pole to a higher frequency to obtain better loop gain and faster stability (obtaining better linearity and faster stability).

The sample and hold amplifier provided by the present disclosure pushes the non-dominant pole farther through a non-Forster circuit and adjusts a feedback factor only through capacitance without increasing additional power consumption.

Specific embodiments are given below to describe the technical solutions of the present disclosure in detail.

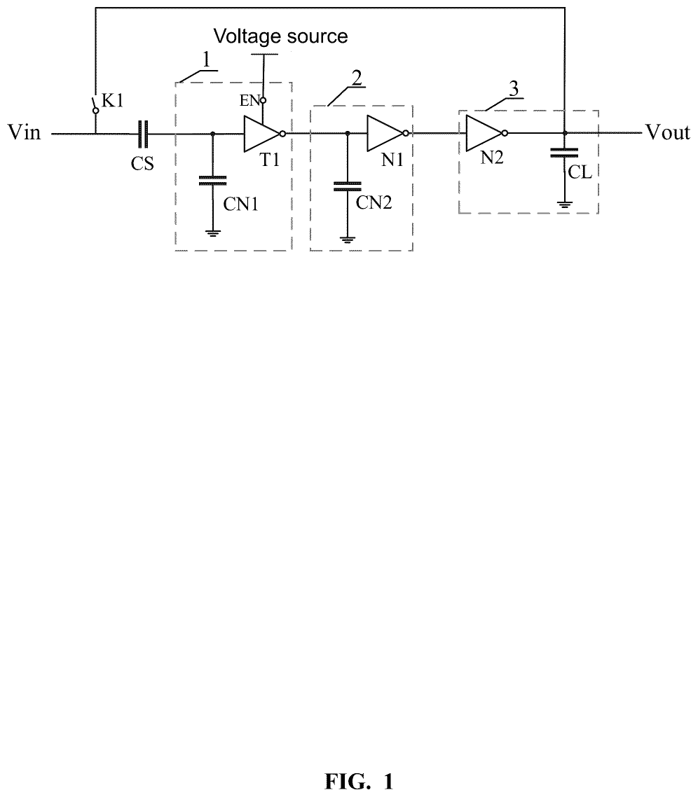

FIG. 1 is a schematic diagram illustrating an exemplary circuit of a sample and hold amplifier according to some embodiments of the present disclosure;

In some embodiments, as shown in FIG. 1, the sample and hold amplifier may include a cascaded configuration of a filter capacitor CS, a first-stage non-Forster circuit 1, a second-stage non-Forster circuit 2, and an output circuit 3. An input terminal of the filter capacitor CS is connected to an output terminal of the output circuit via a first control switch k1; the first-stage non-Forster circuit 1 includes an equivalent tristate gate T1 and a first equivalent negative capacitor CN1; wherein an enable control terminal of the equivalent tristate gate T1 is connected to a voltage source, and an input terminal of the equivalent tristate gate T1 and an first terminal of the first equivalent negative capacitor T1 are connected to form an input terminal of the first-stage non-Forster circuit 1; an output terminal of the equivalent tristate gate T1 forms an output terminal of the first-stage non-Forster circuit 1; and a second terminal of the first equivalent negative capacitor CN1 is grounded.

In some embodiments, the second-stage non-Forster circuit 2 includes a first equivalent non-gate N1 and a second equivalent negative capacitor CN2; wherein an input terminal of the first equivalent non-gate N1 and a first terminal of the second equivalent negative capacitor CN2 are connected to form an input terminal of the second-stage non-Forster circuit 2; an output terminal of the first equivalent non-gate N1 forms an output terminal of the second-stage non-Forster circuit 2; and a second terminal of the second equivalent negative capacitor CN2 is grounded.

In some embodiments, the output circuit 3 includes a second equivalent non-gate N2 and a load capacitor CL; wherein an input terminal of the second equivalent non-gate N2 forms an input terminal of the output circuit 3; an output terminal of the second equivalent non-gate N2 and a first terminal of the load capacitor CL are connected to form an output terminal of the output circuit 3; and an second terminal of the load capacitor CL is grounded; and the first-stage non-Forster circuit 1 and the second-stage non-Forster circuit 2 cancel the internal parasitic capacitor by utilizing an equivalent negative capacitor for improved linearity and faster stability.

The filter capacitor CS refers to a capacitor configured to filter out alternating current (AC) noise components in a circuit. In some embodiments, the filter capacitor performs energy storage and smoothing processing on an input signal, and suppresses high-frequency noise and spike interference, thereby improving a signal-to-noise ratio and stability of the circuit.

The first control switch K1 refers to a switching device capable of selectively turning on or off under the action of an external control signal. In some embodiments, the first control switch K1 is configured to control an operating state of the sample and hold amplifier. When the first control switch K1 is turned on, an input signal Vin is directly transmitted to the output terminal without passing through the sample and hold amplifier. When the first control switch K1 is turned off, the input signal Vin is processed by the sample and hold amplifier and then an output signal Vout is output.

In some embodiments, the equivalent tristate gate T1 is a logic circuit, which is a logic circuit with three states: a high level, a low level, and a high impedance state.

The enable control terminal of the equivalent tristate gate T1 refers to a control port configured to receive an external voltage signal to control an operating state of the tristate buffer. In some embodiments, the enable control terminal of the equivalent tristate gate T1 may determine the state of T1.

The equivalent negative capacitor refers to a circuit behavior or component characteristic that exhibits a current phase that leads a voltage phase by more than 90 degrees in an AC circuit or a complex impedance with a negative imaginary part. In some embodiments, the equivalent negative capacitor includes the first equivalent negative capacitor CN1 and the second equivalent negative capacitor CN2.

The parasitic capacitor refers to a non-ideal capacitor that is inevitably generated due to a physical structure of device itself, wire distribution, and electrical coupling between them. In some embodiments, the parasitic capacitor causes signal delay, bandwidth reduction, and circuit linearity degradation.

In some embodiments, the first-stage non-Forster circuit 1 cancels the internal parasitic capacitor of the sample and hold amplifier through the first equivalent negative capacitor CN1. The second-stage non-Forster circuit 2 cancels the internal parasitic capacitor of the sample and hold amplifier through the second equivalent negative capacitor CN2.

In some embodiments of the present disclosure, the internal parasitic capacitor of the first-stage non-Forster circuit 1 is canceled through the first equivalent negative capacitor CN1, thereby pushing a non-dominant pole of the first-stage non-Forster circuit 1 farther away and improving the phase margin and stability of the circuit.

In some embodiments of the present disclosure, the internal parasitic capacitor of the second-stage non-Forster circuit 2 is canceled through the second equivalent negative capacitor CN2, thereby improving the phase margin and stability of the circuit.

In some embodiments, as shown in FIG. 1, an output terminal of the filter capacitor CS is connected to the first terminal of the first equivalent negative capacitor CN1 and the input terminal of the equivalent tristate gate T1, respectively. The second terminal of the first equivalent negative capacitor CN1 is grounded. The enable control terminal of the equivalent tristate gate T1 is connected to the voltage source. The output terminal of the equivalent tristate gate T1 is connected to a first terminal of the second equivalent negative capacitor CN2 and an input terminal of the first equivalent non-gate N1, respectively. An output terminal of the first equivalent non-gate N1 is connected to an input terminal of the second equivalent non-gate N2. An output terminal of the second equivalent non-gate N2 is connected to another terminal of the first control switch K1 and a first terminal of the load capacitor CL, respectively. A second terminal of the load capacitor CL is grounded. The first control switch K1 is connected between an input terminal of the filter capacitor CS and the first terminal of the load capacitor CL.

In some embodiments, as shown in FIG. 1, an equivalent non-gate is a logic circuit configured to invert a logic value of an input signal. For example, if an input signal of the second-stage non-Forster circuit 2 is at a high level, the output signal of the second-stage non-Forster circuit 2 becomes a low level after the input signal is inverted by the first equivalent non-gate N1.

In some embodiments, the equivalent non-gate includes a first equivalent non-gate N1 and a second equivalent non-gate N2.

In some embodiments, in the design of the sample and hold amplifier, the parasitic capacitor is an unavoidable factor. The parasitic capacitor introduces an additional pole in the sample and hold amplifier. The pole refers to a frequency point in a transfer function of the amplifier where the gain drops to zero or close to zero. These poles reduce the bandwidth of the amplifier, leading to degraded performance of the amplifier. A non-dominant pole refers to a pole that has a relatively small impact on the overall circuit. However, when the non-dominant pole is close to the bandwidth range of the amplifier, the phase margin and stability of the circuit may be affected. In the present disclosure, the first equivalent negative capacitor CN1 and the second equivalent negative capacitor CN2 are introduced in the first-stage non-Forster circuit 1 and the second-stage non-Forster circuit 2, respectively, to cancel the parasitic capacitor, which pushes the non-dominant pole farther away from the operating bandwidth range of the circuit, thereby improving the linearity and stability of the circuit and giving it improved linearity and faster stability.

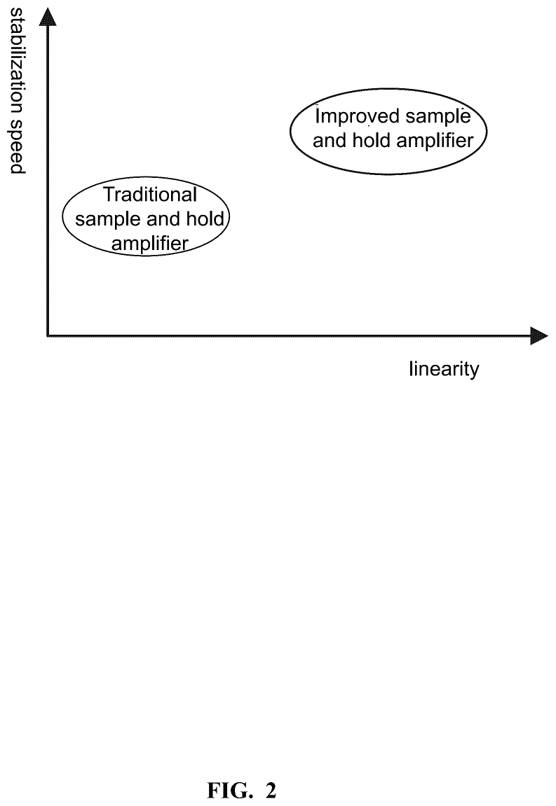

FIG. 2 is a schematic diagram illustrating the performance of a sample and hold amplifier according to some embodiments of the present disclosure. As shown in FIG. 2, compared with a traditional sample and hold amplifier, an improved sample and hold amplifier provided in the present disclosure achieves both a fast stabilization speed and good linearity, enabling a balance between stabilization speed and linearity.

In some embodiments, compared with the traditional sample and hold amplifier, the linearity of the improved sample and hold amplifier may be optimized from a linearity of 60 dB corresponding to the traditional sample and hold amplifier to a linearity being greater than 75 dB corresponding to the improved sample and hold amplifier.

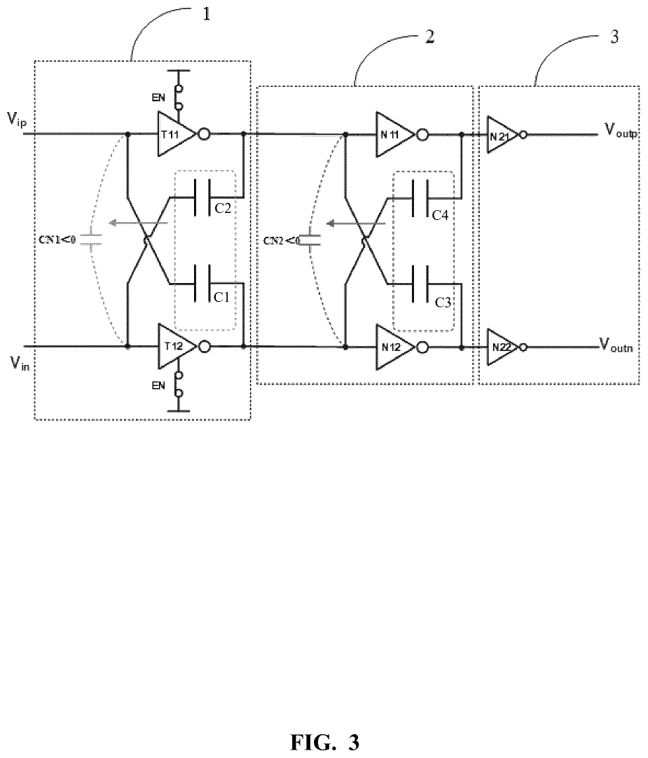

FIG. 3 is another schematic diagram illustrating an exemplary circuit of a sample and hold amplifier according to some embodiments of the present disclosure.

In some embodiments, as shown in FIG. 3, a equivalent tristate gate T1 is formed through a first tristate buffer T11 and a second tristate buffer T12; and a first equivalent negative capacitor CN1 is formed through a first capacitor C1 and a second capacitor C2, wherein an input terminal of the first tristate buffer T11 and an input terminal of the second tristate buffer T12 form an input terminal of the equivalent tristate gate T1 for receiving an input first differential signal; an enable control terminal of the first tristate buffer T11 and an enable control terminal of the second tristate buffer T12 are connected to a voltage source, respectively; an output terminal of the first tristate buffer T11 and an output terminal of the second tristate buffer T12 form an output terminal of the equivalent tristate gate T1, respectively, for outputting a second differential signal. A first terminal of the first capacitor C1 is connected to the input terminal of the first tristate buffer T11 and a second terminal of the first capacitor C1 is connected to the output terminal of the second tristate buffer T12; a first terminal of the second capacitor C2 is connected to the input terminal of the second tristate buffer T12 and a second terminal of the second capacitor C2 is connected to the output terminal of the first tristate buffer T11; wherein a capacitance of the first capacitor C1 and a capacitance of the second capacitor C2 are equal, and through the first capacitor C2 and the second capacitor C2, a negative capacitor is effectively connected in parallel between the input terminal of the first tristate buffer T12 and the input terminal of the second tristate buffer T12.

In some embodiments, a negative capacitor is equivalently connected between the input terminal of the first tristate buffer T11 and the input terminal of the second tristate buffer T12, and the negative capacitor is the first equivalent negative capacitor CN1.

The first differential signal refers to a pair of AC signals that have equal amplitudes but opposite phases. In some embodiments, the equivalent tristate gate T1 receives the first differential signal. The first differential signal is input by an external device through an input terminal Vip of the first tristate buffer T11 and an input terminal Vin of the second tristate buffer T12.

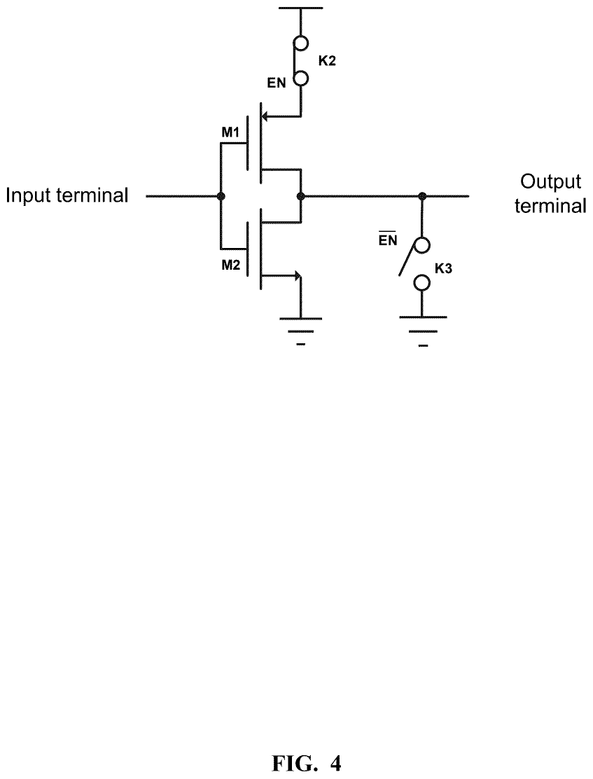

In some embodiments, as shown in FIG. 3, EN represents an enable control terminal of the first tristate buffer T11 or an enable control terminal of the second tristate buffer T12. The capacitance of the first equivalent negative capacitor CN1 and the capacitance of the second equivalent negative capacitor CN2 are negative. Voutp and Voutn are output signals after a third differential signal is processed by a third non-gate N21 and a fourth non-gate N22. FIG. 4 is a schematic diagram illustrating an exemplary circuit of a tristate circuit according to some embodiments of the present disclosure.

A Metal-Oxide-Semiconductor Field-Effect Transistor (MOSFET) is a field-effect transistor manufactured using planar technology, which is referred to as a MOSFET.

In some embodiments, as shown in FIG. 4, a first tristate buffer T11 and/or a second tristate buffer T12 includes a second control switch K2, a first MOSFET M1, a second MOSFET M2, and a third control switch K3. An input terminal of a tristate buffer is formed by connecting a gate of the first MOSFET and a gate of the second MOSFET; an output terminal of the tristate buffer is formed by connecting a drain of the first MOSFET and a drain of the second MOSFET; a source of the first MOSFET is connected to a voltage source through the second control switch; the second control switch is controlled by an initial control signal from a controller; and a source of the second MOSFET is grounded through the third control switch; the third control switch is controlled by an inverted signal from the initial control signal.

The input terminal of the tristate buffer formed by connecting the gate of the first MOSFET M1 and the gate of the second MOSFET M2 is an input terminal of the first tristate buffer T11 or an input terminal of the second tristate buffer T12. The output terminal of the tristate buffer formed by connecting the drain of the first MOSFET M1 and the drain of the second MOSFET M2 is an output terminal of the first tristate buffer T11 or an output terminal of the second tristate buffer T12.

The controller refers to a logic unit that generates an initial control signal and an inverted signal of the initial control signal to turn off or turn on a power supply and a ground path of the tristate buffer, thereby controlling an output state of the tristate buffer.

The inverted signal is a signal where a phase difference between an input signal and an output signal is 180 degrees, i.e., a waveform of the output signal is completely opposite to that of the input signal.

The initial control signal refers to a binary digital signal generated by the controller based on a clock or state logic.

In some embodiments, the third control switch K3 is controlled by the inverted signal of the initial control signal, indicating that the turn-on and turn-off state is controlled by a signal opposite to the initial control signal.

In some embodiments, as shown in FIG. 3, the first equivalent non-gate N1 is formed through a first non-gate N11 and a second non-gate N12, and the second equivalent negative capacitor CN2 is formed through a third capacitor C3 and a fourth capacitor C4.

An input terminal of the first non-gate N11 and an input terminal of the second non-gate N12 form the input terminal of the first equivalent non-gate N1 for receiving the second differential signal.

An output terminal of the first non-gate N11 and an output terminal of the second non-gate N12 form the output terminal of the first equivalent non-gate N1 and are configured to output a third differential signal.

A first terminal of the third capacitor C3 is connected to the input terminal of the first non-gate N11 and a second terminal of the third capacitor C3 is connected to the output terminal of the second non-gate N12.

A first terminal of the fourth capacitor C4 is connected to the input terminal of the second non-gate N12 and a second terminal of the fourth capacitor C4 is connected to the output terminal of the first non-gate N11.

A capacitance of the third capacitor C3 and a capacitance of the fourth capacitor C4 are equal, and through the third capacitor C3 and the fourth capacitor C4, a negative capacitor is effectively connected in parallel between the input terminal of the first non-gate N11 and the input terminal of the second non-gate N12. In some embodiments, a negative capacitor is equivalently formed between the input terminal of the first non-gate N11 and the input terminal of the second non-gate N12, and the negative capacitor is the second equivalent negative capacitor CN2.

In some embodiments, the capacitance of the first capacitor C1 and the capacitance of the third capacitor C3 are set according to actual needs. For example, the capacitance of the first capacitor C1 may be less than or equal to the capacitance of the third capacitor C3.

In some embodiments, the capacitance of the first capacitor C1 is greater than the capacitance of the third capacitor C3.

In some embodiments, as shown in FIG. 3, the second equivalent non-gate N2 is formed by two non-gates connected in parallel. As shown in FIG. 3, the second equivalent non-gate N2 is formed by a third non-gate N21 and a fourth non-gate N22.

In some embodiments, a first equivalent negative capacitor CN1 formed by a first capacitor C1 and a second capacitor C2 is a negative capacitor. A second equivalent negative capacitor CN2 formed by a third capacitor C3 and a fourth capacitor C4 is a negative capacitor.

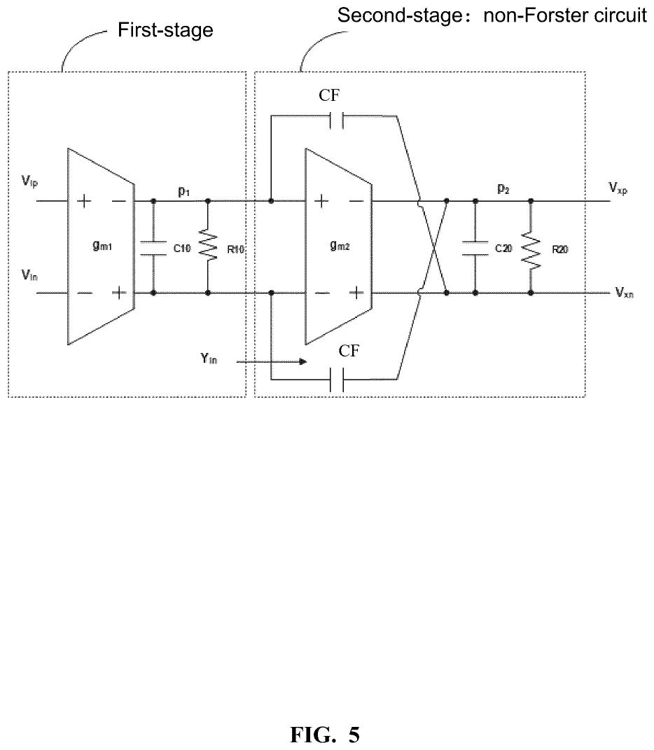

FIG. 5 is a schematic diagram illustrating an exemplary circuit of a two-stage sample and hold amplifier with a non-Forster circuit according to some embodiments of the present disclosure. As shown in FIG. 5, a feedback capacitor CF is placed between an input terminal and an output terminal of a second stage of the two-stage sample and hold amplifier, with different polarities. P1 and P2 represent a pole of a first-stage sample and hold amplifier and a pole of a second-stage sample and hold amplifier, respectively. An input admittance Yᵢₙ is calculated to further derive an equivalent capacitance of the two feedback capacitors CF. As shown in FIG. 5, Vin and Vip are input terminals of the differential signal, where Vin is a negative input terminal and Vip is a positive input terminal. Vxp and Vxn represent output differential signal terminals, where Vxp is a positive output terminal and Vxn is a negative output terminal. gₘ₁ and gₘ₂ are transconductances of a first-stage sample and hold amplifier and a second-stage sample and hold amplifier of a first amplifier, respectively.

In some embodiments, an equivalent capacitance of the two feedback capacitors CF is calculated by following formula (1):

$${C}_{F , eff} = CF ( 1 - \frac{{ω}^{2} \frac{CF}{CF + {C}_{20}} + 2 {g}_{m 2} {R}_{20} {ω}_{p 2}^{2}}{{ω}^{2} + 4 {ω}_{p 2}^{2}} ) \qquad ( 1 )$$

In the formula (1), C_{F,eff} is the equivalent capacitance of the two feedback capacitors CF.
CF is a capacitance of the feedback capacitor.
C₂₀ is a capacitance of a capacitor C₂₀ on a second stage in the two-stage amplifier.
R₂₀ is a resistance of a resistor R₂₀ on the second stage in the two-stage amplifier.
ω is a frequency variable.
ωₚ₂ is a frequency value of the pole of the second-stage amplifier.
gₘ₂ is a transconductance of the second-stage amplifier.

In some embodiments, C_{F,eff} is negatively correlated with ω. When ω is relatively low, C_{F,eff} is relatively large. As w increases, C_{F,eff} gradually decreases.

In some embodiments, when

$$ω \to 0 ⇒ {C}_{F , eff} = CF ( 1 - \frac{{g}_{m 2} {R}_{20}}{4} ) ;$$

when

$$ω \to {ω}_{p 2} ( {g}_{m 2} {R}_{2} - 2 ) ( 2 + \frac{CF}{C 2} ) , {C}_{F , eff} \to 0 .$$

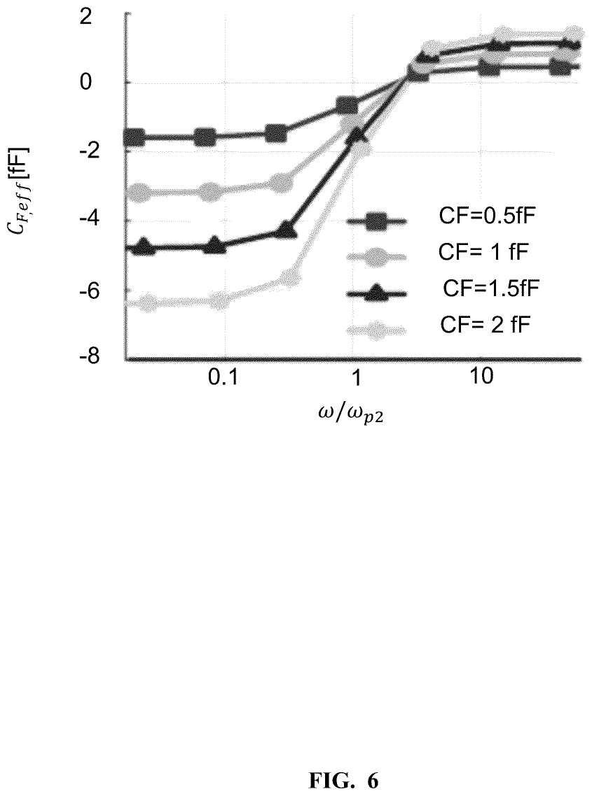

FIG. 6 is a schematic diagram illustrating a change curve of equivalent capacitances of two feedback capacitors in a two-stage amplifier with a non-Forster circuit according to some embodiments of the present disclosure. As shown in FIG. 6, the equivalent capacitance includes following characteristics: at low frequencies (e.g., when ω/ωₚ₂ is below 5), the equivalent capacitance is negative, but at high frequencies (e.g., when ω/ωₚ₂ is above 5), the equivalent capacitance becomes positive. Therefore, in the two-stage sample and hold amplifier, if a frequency of a pole P2 of the second-stage sample and hold amplifier is higher than a frequency of a pole P1 of the first-stage sample and hold amplifier, the characteristic expands a bandwidth of the first stage. The non-Forster circuit accelerates a stabilization speed of a previous stage by introducing a negative capacitor. In addition, the non-Forster circuit takes effect immediately when the amplifier starts working, avoiding complexity of adjusting the operating point of the negative capacitor during a fast amplification process.

In some embodiments, a verification test is performed on the sample and hold amplifier shown in FIG. 3 to verify the effect of the sample and hold amplifier.

In some embodiments, the sample and hold amplifier shown in FIG. 3 includes two stages of a non-Forster circuit. Fast stability is achieved and performance in a hold phase is optimized through the two stages of the non-Forster circuit. Because an output stage of a second stage non-Forster circuit 2 is small, a light capacitive load is presented, the response speed of the second-stage non-Forster circuit 2 is relatively fast. To further improve the stability of the overall circuit, the second-stage non-Forster circuit 2 uses a negative capacitor to compensate for the parasitic capacitor output from the first-stage non-Forster circuit 1, thereby pushing away the non-dominant pole.

In addition, the first-stage non-Forster circuit 1 is mainly configured to compensate for the parasitic capacitor at the input terminal of the overall circuit, thereby increasing the feedback factor, and significantly improving the linearity and gain bandwidth of the circuit.

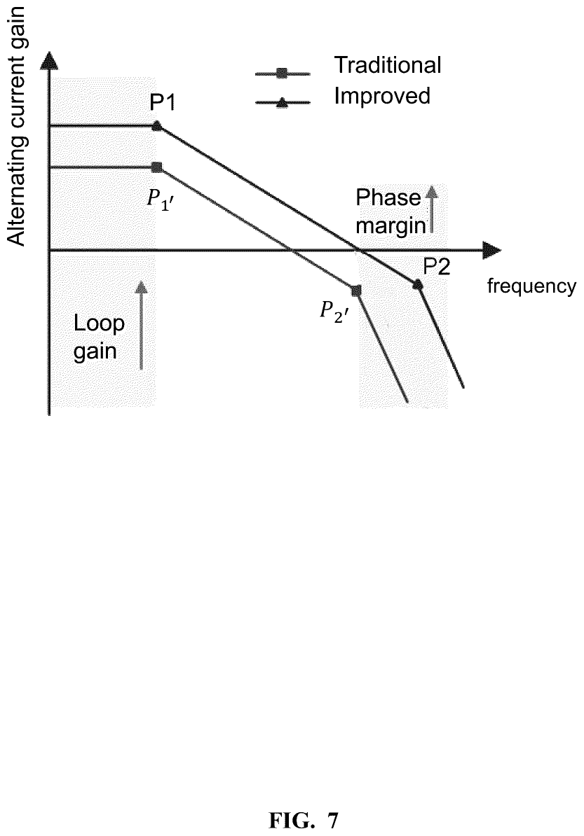

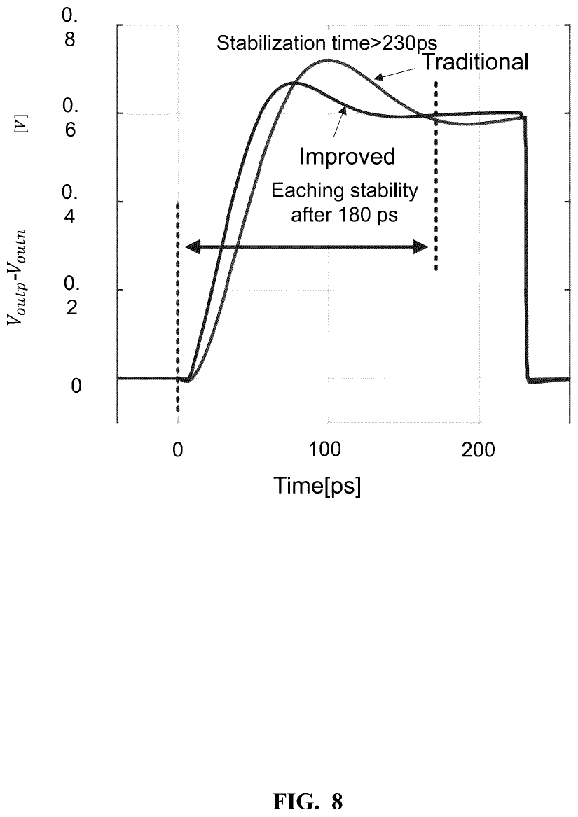

FIG. 7 is a schematic diagram illustrating a test result of a sample and hold amplifier according to some embodiments of the present disclosure. FIG. 8 is a schematic diagram illustrating a transient response of a sample and hold amplifier according to some embodiments of the present disclosure.

In some embodiments, as shown in FIG. 7 and FIG. 8, FIG. 7 and FIG. 8 compare a sample and hold amplifier provided by the present disclosure (labeled as improved in the figures) with a traditional sample and hold amplifier (labeled as traditional in the figures).

In some embodiments, as shown in FIG. 7, an abscissa in FIG. 7 represents a frequency of an input signal of the sample and hold amplifier, and an ordinate represents an alternating current (AC) gain or a loop gain. P_{1′} and P_{2′} represent a pole of a traditional first-stage sample and hold amplifier and a pole of a traditional second-stage sample and hold amplifier, respectively. FIG. 7 shows a variation of the AC gain with frequency. As shown in FIG. 7 and FIG. 8, for a multi-GS/s ADC input buffer, it is required to maintain good stability while responding quickly. Compared with the traditional sample and hold amplifier, the improved sample and hold amplifier provided by the present disclosure includes a first-stage non-Forster circuit 1 and a second-stage non-Forster circuit 2 that work in coordination, resulting in larger loop gain and phase margin. Meanwhile, the first-stage non-Forster circuit 1 and the second-stage non-Forster circuit 2 provide a gain of about 40 dB, thereby effectively suppressing nonlinear effects.

In some embodiments, a stabilization speed is measured by the length of a stabilization time. For example, a shorter stabilization time corresponds to a greater stabilization speed. In addition, from a transient response perspective, as shown in FIG. 8, compared to a stabilization time being greater than 230 ps (e.g., 230 ps) for the traditional sample and hold amplifier, the sample and hold amplifier achieves a short stabilization time of reaching stability after 180 ps, shortening the stabilization time by about 50 ps. The stabilization speed is improved, and power consumption is only 6 mW, meeting requirements of the input buffer of the high-speed analog-to-digital converter for a fast response.

In addition, as shown in FIG. 8, the sample and hold circuit provided by the present disclosure effectively reduces a pre-ringing phenomenon of the circuit. The pre-ringing phenomenon is a common oscillation phenomenon during a signal transition, which usually affects the transient response and stability of the system. By setting the two stages of the non-Forster circuit, the gain bandwidth and phase margin of the circuit are optimized, making the signal transition smoother, improving the slew rate, and ensuring that a stable state is reached in a shorter time.

In the sample and hold amplifier provided by the embodiments of the present disclosure, the first-stage non-Forster circuit focuses on providing preliminary gain and parasitic capacitor compensation, ensuring that the circuit effectively processes the input signal and reduces the impact of a non-dominant pole. The second-stage non-Forster circuit further optimizes gain and stability. In particular, due to its smaller output stage and lighter capacitive load, its response speed is relatively fast, thereby achieving a faster stabilization time for the overall circuit. A synergistic effect of the two stages of the non-Forster circuit not only improves linearity and gain bandwidth of the sample and hold amplifier but also effectively suppresses nonlinear distortion in the signal, ensuring a high-performance input buffer function.

The sample and hold amplifier provided in some embodiment includes the first-stage non-Forster circuit and the second-stage non-Forster circuit. The first-stage non-Forster circuit and the second-stage non-Forster circuit cancel an internal parasitic capacitor by utilizing an equivalent negative capacitor. In this way, nonlinear distortion caused by the parasitic capacitor is reduced, and the linearity of the sample and hold amplifier is improved. In addition, a design of the first-stage non-Forster circuit focuses on providing preliminary gain and parasitic capacitor compensation, ensuring that the circuit effectively processes the input signal and reduces the impact of a non-dominant pole on overall performance. The second-stage non-Forster circuit further optimizes gain and stability, thereby enabling the sample and hold circuit to achieve faster stability overall.

Corresponding to the embodiments of the sample and hold amplifier described above, the present disclosure also provides an embodiment of a high-speed analog-to-digital converter. The high-speed analog-to-digital converter provided in the present disclosure is described below.

The high-speed analog-to-digital converter provided in the present disclosure includes at least one sample and hold amplifier.

In some embodiments, the high-speed analog-to-digital converter also includes an input buffer and a sub analog-to-digital converter. The sample and hold amplifier is disposed between the input buffer and the sub analog-to-digital converter.

In some embodiments, a correspondence between a count of input buffers and a count of sample and hold amplifiers may be a one-to-one relationship. That is, an input buffer is connected to a sample and hold amplifier.

In some embodiments, the correspondence between the count of input buffers and the count of sample and hold amplifiers may also be a one-to-many relationship. That is, an input buffer is connected to a plurality of sample and hold amplifiers.

In some embodiments, a correspondence between the count of sample and hold amplifiers and a count of sub analog-to-digital converters may also be a one-to-one relationship. That is, a sample and hold amplifier is connected to a sub analog-to-digital converter.

In some embodiments, the correspondence between the count of sample and hold amplifiers and the count of sub analog-to-digital converters may be a one-to-many relationship. That is, a sample and hold amplifier is connected to a plurality of sub analog-to-digital converters.

In some embodiments, the correspondence between the count of input buffers and the count of sample and hold amplifiers, and the correspondence between the count of sample and hold amplifiers and the count of sub analog-to-digital converters, are set according to actual needs. As an example, in one possible implementation, an input buffer is connected to a sample and hold amplifier, a sample and hold amplifier is connected to four sub analog-to-digital converters, or the like.

In the high-speed analog-to-digital converter provided in some embodiments, the sample and hold amplifier pushes a non-dominant pole farther away through a two-stage non-Foster circuit and increases a feedback factor only through a capacitor without increasing additional power consumption. The sample and hold amplifier has better linearity and faster stability. This is beneficial for improving the overall performance of the high-speed analog-to-digital converter.

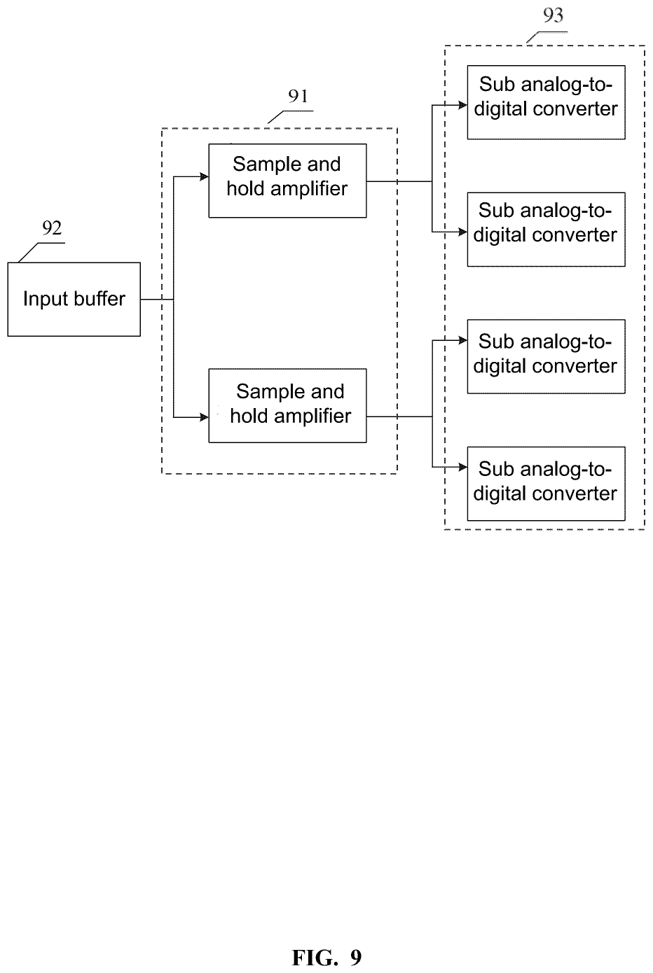

FIG. 9 is a schematic diagram illustrating an exemplary circuit of a high-speed analog-to-digital converter according to some embodiments of the present disclosure.

In some embodiments, as shown in FIG. 9, the high-speed analog-to-digital converter provided in the embodiment includes two sample and hold amplifiers 91. The high-speed analog-to-digital converter also includes an input buffer 92 and four sub analog-to-digital converters 93.

In some embodiments, an output terminal of the input buffer is connected to input terminals of the two sample and hold amplifiers, respectively; an output terminal of each of the two sample and hold amplifiers is connected to output terminals of the two sub analog-to-digital converters, respectively; and an output terminal of the high-speed analog-to-digital converter is formed by connecting output terminals of the four sub analog-to-digital converters.

The high-speed analog-to-digital converter merges output data of the four sub analog-to-digital converters by a time interleaving technique to increase a sampling rate.

The sample and hold amplifier refers to a circuit configured to capture and maintain an instantaneous voltage of an analog signal. The input buffer refers to an analog circuit unit configured for impedance matching and signal driving. The sub analog-to-digital converter refers to a module configured to convert an analog signal into a digital signal.

The sampling rate refers to a count of times per second that the high-speed analog-to-digital converter samples the analog signal. In some embodiments, a sampling rate of a single channel is about 850 MS/s, and a sampling rate of four combined channels of the four sub analog-to-digital converters is about 3.4 GS/s, etc.

The time interleaving technique refers to a technique for achieving a sampling rate far higher than a sampling rate achievable by a single ADC by operating the plurality of high-speed analog-to-digital converters in parallel.

In some embodiments, an input buffer 92 is configured to transmit an external input signal to the sample and hold amplifier and provide a certain current driving capability. The input buffer 92 isolates an internal circuit of the high-speed analog-to-digital converter from an external signal source, preventing an impedance change of the signal source from affecting the performance of the high-speed analog-to-digital converter. In addition, the input buffer 92 may also perform signal amplification to ensure an amplitude of the signal is suitable for an input range of the high-speed analog-to-digital converter, or the like.

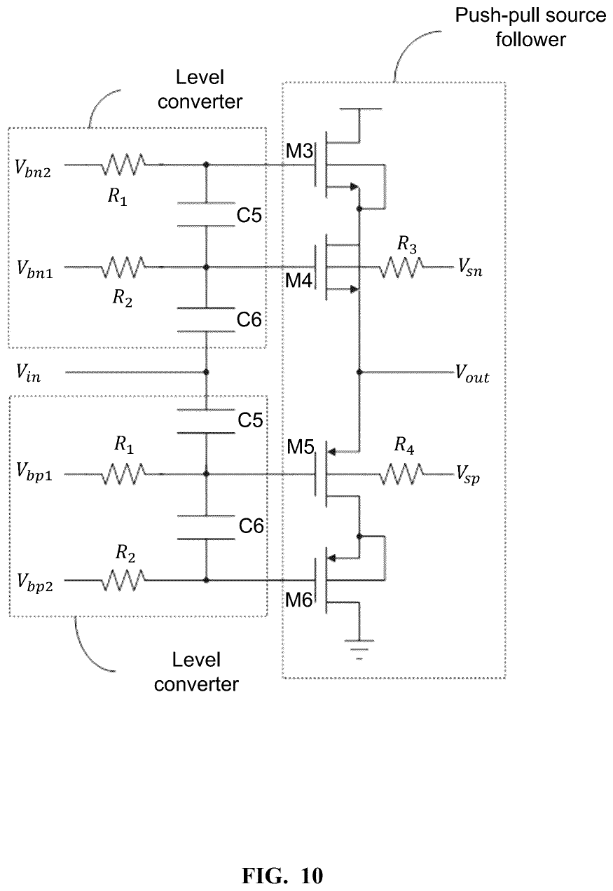

FIG. 10 is a schematic diagram illustrating an exemplary circuit of an input buffer according to some embodiments of the present disclosure.

In some embodiments, as shown in FIG. 10, the input buffer includes two level converters and a push-pull source follower.

Each level converter includes a first resistor R1, a second resistor R2, a fifth capacitor C5, and a sixth capacitor C6, a first terminal of the first resistor R1 and a first terminal of the second resistor R2 form a bias input terminal of the level converter to receive a bias voltage; a second terminal of the first resistor R1 and a second terminal of the second resistor R2 form an output terminal of the level converter, respectively.

The fifth capacitor C5 is connected between a second terminal of the first resistor R1 and a second terminal of the second resistor R2.

A first terminal of the sixth capacitor C6 forms a signal input terminal of the level converter for receiving an input signal.

The push-pull source follower includes a third MOSFET M3, a fourth MOSFET M4, a fifth MOSFET M5, a sixth MOSFET M6, a third resistor R3, and a fourth resistor R4.

A gate of each MOSFET forms an input terminal of the push-pull source follower, and the input terminal of the push-pull source follower is connected to an output terminal of each of the two level converters.

A drain of the third MOSFET M3 is connected to a voltage source, and a substrate of the third MOSFET M3 is connected to a drain of the fourth MOSFET M4 after being connected to a source of the third MOSFET M3.

A substrate of the fourth MOSFET M4 is connected to a first terminal of the third resistor R3, and another terminal of the third resistor R3 forms a first bias input terminal of the push-pull source follower for receiving a bias voltage.

A source of the fourth MOSFET M4 is connected to a source of the fifth MOSFET M5 to form an output terminal of the push-pull source follower.

A substrate of the fifth MOSFET M5 is connected to a first terminal of the fourth resistor R4; and a second terminal of the fourth resistor R4 forms a second bias input terminal of the push-pull source follower for receiving a bias voltage.

A drain of the fifth MOSFET M5 is connected to a source of the sixth MOSFET M6 and the source of the sixth MOSFET M6 is connected to a substrate of the sixth MOSFET M6; and a drain of the sixth MOSFET M6 is grounded.

The bias input terminal refers to a terminal configured to receive a bias voltage provided externally. The bias voltage refers to a voltage signal provided to the bias input terminal configured to set a direct current (DC) operating point of the level converter to keep the level converter within a suitable operating range.

The signal input terminal refers to a port configured to receive an input signal. The input signal refers to a voltage or current signal provided by an external circuit and applied to the signal input terminal.

The gate of each MOSFET refers to a gate of the third MOSFET M3, a gate of the fourth MOSFET M4, a gate of the fifth MOSFET M5, and a gate of the sixth MOSFET M6.

In some embodiments, resistances of the first resistor R1, the second resistor R2, the third resistor R3, and the fourth resistor R4 are set according to actual needs. In addition, a capacitance of the fifth capacitor C5 and a capacitance of the sixth capacitor C6 are also set according to actual needs.

In some embodiments of the present disclosure, the third resistor R3 and the fourth resistor R4 are respectively connected to the substrates of the fourth MOSFET M4 and the fifth MOSFET M5, which reduces a voltage change between a source and the substrate and improves linearity of high-frequency signals.

In some embodiments, as shown in FIG. 9, the sample and hold amplifier 91 is disposed between the input buffer 92 and the four sub analog-to-digital converters 93. The sample and hold amplifier 91 is configured to sample and hold a voltage value of the input signal. In some embodiments, in a sampling phase, the sample and hold amplifier 91 captures an instantaneous voltage value of the input signal onto a capacitor. In a hold phase, the voltage value on the capacitor is maintained unchanged so that the subsequent sub analog-to-digital converter 93 can perform stable digital conversion on the voltage value. In this way, the instantaneous fluctuation of the signal may be eliminated, and the conversion accuracy can be improved.

In some embodiments, as shown in FIG. 9, the four sub analog-to-digital converters 93 operate in parallel based on the time interleaving technique. Each sub analog-to-digital converter 93 samples the input signal at different time intervals, performs analog-to-digital conversion on the sampled signal to generate a corresponding digital output, and finally combines these digital outputs to achieve a higher total sampling rate.

In some embodiments, each sub analog-to-digital converter 93 includes a 4-bit flash ADC, an 8× residue amplifier, and a 9-bit SAR ADC with 1-bit redundancy.

In some embodiments, each sub analog-to-digital converter 93 is a 12-bit 800 MS/s ADC slice. By combining four 12-bit 800 MS/s ADC slices using the time interleaving technique, a 3.2 GS/s 12-bit high-speed analog-to-digital converter may be implemented.

It should be noted that the high-speed analog-to-digital converter provided in some embodiments may be manufactured using a 28 nm Complementary Metal-Oxide-Semiconductor (CMOS) process.

In some embodiments, to verify the performance of the high-speed analog-to-digital converter provided in the present disclosure, a performance test is performed. Details are as follows:

In some embodiments, an output spectrum of the high-speed analog-to-digital converter is tested at a sampling rate of 3.2 GS/s. Results show that the analog-to-digital converter achieves a Signal to Noise and Distortion Ratio (SNDR) of 54.1 dB and a Spurious-Free Dynamic Range (SFDR) of 78.4 dB for a 30 MHz input. For a 1500 MHZ input, the analog-to-digital converter achieves a SNDR of 52.7 dB and a SFDR of 74.3 dB, with a power consumption of 150 mW.

The high-speed analog-to-digital converter provided in this embodiment simplifies time offset adjustment for the two sample and hold amplifier paths and reduces bandwidth mismatch among the four sub analog-to-digital converters.

The present disclosure also provides an electronic device. The electronic device includes the high-speed analog-to-digital converter described above.

The sample and hold amplifier, the high-speed analog-to-digital converter, and the electronic device provided in the present disclosure are configured to enable the sample and hold amplifier to achieve better linearity and faster stability, thereby improving the overall performance of the high-speed analog-to-digital converter.

The sample and hold amplifier, the high-speed analog-to-digital converter, and the electronic device provided in the present disclosure include a first-stage non-Forster circuit and a second-stage non-Forster circuit arranged in the sample and hold amplifier. The first-stage non-Forster circuit and the second-stage non-Forster circuit use an equivalent negative capacitor to cancel an internal parasitic capacitor. In this way, nonlinear distortion caused by the parasitic capacitor can be reduced, and linearity of the sample and hold amplifier can be improved. In addition, a design of the first-stage non-Forster circuit focuses on providing preliminary gain and parasitic capacitor compensation, ensuring that the circuit can effectively process an input signal and reduce an impact of a non-dominant pole on overall performance. The second-stage non-Forster circuit further optimizes gain and stability, thereby enabling the sample and hold circuit to achieve faster stability overall.

The foregoing descriptions are merely preferred embodiments of the present disclosure and are not intended to limit the present disclosure. Any modification, equivalent replacement, improvement, or the like made within the spirit and principle of the present disclosure shall be included within the protection scope of the present disclosure.

The basic concepts have been described above. Obviously, to a person skilled in the art, the foregoing detailed disclosure is merely an example and does not constitute a limitation to the present disclosure. Although not explicitly stated herein, a person skilled in the art may make various modifications, improvements, and amendments to the present disclosure. Such modifications, improvements, and amendments are suggested in the present disclosure. Therefore, such modifications, improvements, and amendments still fall within the spirit and scope of the exemplary embodiments of the present disclosure.

In addition, unless explicitly stated in the claims, an order of processing elements and sequences, use of numbers and letters, or use of other names described in the present disclosure is not used to limit an order of processes and methods of the present disclosure. Although some embodiments of the invention currently considered useful are discussed in the foregoing disclosure through various examples, it should be understood that such details are for illustrative purposes only. The appended claims are not limited to the disclosed embodiments. On the contrary, the claims are intended to cover all modifications and equivalent combinations that conform to the essence and scope of the embodiments of the present disclosure. For example, although the implementation of various components described above may be embodied in a hardware device, it may also be implemented as a software only solution, e.g., an installation on an existing server or mobile device.

Finally, it should be understood that the embodiments described in the present disclosure are merely used to illustrate principles of the embodiments of the present disclosure. Other variations may also fall within the scope of the present disclosure. Therefore, by way of example and not limitation, alternative configurations of the embodiments of the present disclosure may be considered consistent with the teachings of the present disclosure. Accordingly, the embodiments of the present disclosure are not limited to the embodiments explicitly introduced and described in the present disclosure.

What is claimed is:

1. A sample and hold amplifier wherein the sample and hold amplifier comprises a cascaded configuration of a filter capacitor, a first-stage non-Forster circuit, a second-stage non-Forster circuit, and an output circuit, wherein
an input terminal of the filter capacitor is connected to an output terminal of the output circuit via a first control switch;
the first-stage non-Forster circuit includes an equivalent tristate gate and a first equivalent negative capacitor; wherein an enable control terminal of the equivalent tristate gate is connected to a voltage source, and an input terminal of the equivalent tristate gate and an first terminal of the first equivalent negative capacitor are connected to form an input terminal of the first-stage non-Forster circuit; an output terminal of the equivalent tristate gate forms an output terminal of the first-stage non-Forster circuit; and a second terminal of the first equivalent negative capacitor is grounded;
the second-stage non-Forster circuit includes a first equivalent non-gate and a second equivalent negative capacitor; wherein an input terminal of the first equivalent non-gate and a first terminal of the second equivalent negative capacitor are connected to form an input terminal of the second-stage non-Forster circuit; an output terminal of the first equivalent non-gate forms an output terminal of the second-stage non-Forster circuit; and a second terminal of the second equivalent negative capacitor is grounded;
the output circuit includes a second equivalent non-gate and a load capacitor; wherein an input terminal of the second equivalent non-gate forms an input terminal of the output circuit; an output terminal of the second equivalent non-gate and a first terminal of the load capacitor are connected to form an output terminal of the output circuit; and an second terminal of the load capacitor is grounded; and
the first-stage non-Forster circuit and the second-stage non-Forster circuit cancel an internal parasitic capacitor by utilizing an equivalent negative capacitor for improved linearity and faster stability.

2. The sample and hold amplifier of claim 1, wherein the equivalent tristate gate is formed through a first tristate buffer and a second tristate buffer; and the first equivalent negative capacitor is formed through a first capacitor and a second capacitor; wherein
an input terminal of the first tristate buffer and an input terminal of the second tristate buffer form the input terminal of the equivalent tristate gate for receiving an input first differential signal;
an enable control terminal of the first tristate buffer and an enable control terminal of the second tristate buffer are connected to the voltage source, respectively;
an output terminal of the first tristate buffer and an output terminal of the second tristate buffer form the output terminal of the equivalent tristate gate, respectively, for outputting a second differential signal;
a first terminal of the first capacitor is connected to the input terminal of the first tristate buffer, and a second terminal of the first capacitor is connected to the output terminal of the second tristate buffer;
a first terminal of the second capacitor is connected to the input terminal of the second tristate buffer, and a second terminal of the second capacitor is connected to the output terminal of the first tristate buffer;
wherein a capacitance of the first capacitor and a capacitance of the second capacitor are equal, and through the first capacitor and the second capacitor, a negative capacitor is effectively connected in parallel between the input terminal of the first tristate buffer and the input terminal of the second tristate buffer.

3. The sample and hold amplifier of claim 2, wherein the first equivalent non-gate is formed through a first non-gate and a second non-gate, and the second equivalent negative capacitor is formed through a third capacitor and a fourth capacitor; wherein
an input terminal of the first non-gate and an input terminal of the second non-gate form the input terminal of the first equivalent non-gate for receiving the second differential signal;
an output terminal of the first non-gate and an output terminal of the second non-gate form the output terminal of the first equivalent non-gate for outputting a third differential signal;
a first terminal of the third capacitor is connected to the input terminal of the first non-gate and a second terminal of the third capacitor is connected to an output terminal of the second non-gate;
a first terminal of the fourth capacitor is connected to the input terminal of the second non-gate and a second terminal of the fourth capacitor is connected to the output terminal of the first non-gate;
wherein a capacitance of the third capacitor and a capacitance of the fourth capacitor are equal, and through the third capacitor and the fourth capacitor, a negative capacitor is effectively connected in parallel between the input terminal of the first non-gate and the input terminal of the second non-gate.

4. The sample and hold amplifier of claim 2, wherein at least one of the first tristate buffer and the second tristate buffer includes a second control switch, a first Metal Oxide Semiconductor (MOS) tube, a second MOSFET, and a third control switch; wherein,
an input terminal of a tristate buffer is formed by connecting a gate of the first MOSFET and a gate of the second MOSFET;
an output terminal of the tristate buffer is formed by connecting a drain of the first MOSFET and a drain of the second MOSFET;
a source of the first MOSFET is connected to the voltage source through the second control switch; the second control switch is controlled by an initial control signal from a controller; and
a source of the second MOSFET is grounded through the third control switch; the third control switch is controlled by an inverted signal from the initial control signal.

5. The sample and hold amplifier of claim 1, wherein the second equivalent non-gate is formed by two non-gates connected in parallel.

6. The sample and hold amplifier of claim 3, wherein the capacitance of the first capacitor is greater than the capacitance of the third capacitor.

7. A high-speed analog-to-digital converter, wherein the high-speed analog-to-digital converter comprises at least one sample and hold amplifier of claim 1.

8. The high-speed analog-to-digital converter of claim 7, wherein the high-speed analog-to-digital converter includes two sample and hold amplifiers; and the high-speed analog-to-digital converter further includes an input buffer and four sub analog-to-digital converters; wherein
an output terminal of the input buffer is connected to input terminals of the two sample and hold amplifiers, respectively; an output terminal of each of the two sample and hold amplifiers is connected to output terminals of the two sub analog-to-digital converters, respectively; and an output terminal of the high-speed analog-to-digital converter is formed by connecting output terminals of the four sub analog-to-digital converters;
wherein the high-speed analog-to-digital converter merges output data of the four sub analog-to-digital converters by time interleaving technique to increase a sampling rate.

9. The high-speed analog-to-digital converter of claim 8, wherein the input buffer includes two level converters and a push-pull source follower; wherein
each level converter includes a first resistor, a second resistor, a fifth capacitor, and a sixth capacitor; a first terminal of the first resistor and a first terminal of the second resistor form a bias input terminal of the level converter for receiving a bias voltage, respectively; a second terminal of the first resistor and a second terminal of the second resistor form an output terminal of the level converter, respectively;
the fifth capacitor is connected between the second terminal of the first resistor and the second terminal of the second resistor;
a first terminal of the sixth capacitor forms a signal input terminal of the level converter for receiving an input signal;
the push-pull source follower includes a third MOSFET, a fourth MOSFET, a fifth MOSFET, a sixth MOSFET, a third resistor, and a fourth resistor; wherein
a gate of each MOSFET forms an input terminal of the push-pull source follower, and the input terminal of the push-pull source follower is connected to an output terminal of each of the two level converters;
a drain of the third MOSFET is connected to a voltage source and a substrate of the third MOSFET is connected to the drain of the fourth MOSFET after being connected to a source of the third MOSFET;
a substrate of the fourth MOSFET is connected to a first terminal of the third resistor, and another terminal of the third resistor forms a first bias input terminal of the push-pull source follower for receiving the bias voltage;
a source of the fourth MOSFET is connected to a source of the fifth MOSFET to form an output terminal of the push-pull source follower;
a substrate of the fifth MOSFET is connected to a first terminal of the fourth resistor, a second terminal of the fourth resistor forms a second bias input terminal of the push-pull source follower for receiving the bias voltage;
a drain of the fifth MOSFET is connected to a source of the sixth MOSFET, and the source of the sixth MOSFET is connected to a substrate of the sixth MOSFET; and a drain of the sixth MOSFET is grounded.

10. An electronic device, wherein the electronic device comprises the high-speed analog-to-digital converter of claim 7.
